(19) United States
(12) Patent Application Publication
(10) Pub. No.: US 2025/0125292 A1
(43) Pub. Date: Apr. 17, 2025

(54) SIDE-WETTABLE PACKAGE WITH EDGE-RECESSED BOND PADS

(71) Applicant: PANJIT INTERNATIONAL INC., KAOHSIUNG CITY (TW)

(72) Inventors: CHUNG-HSIUNG HO, Kaohsiung City (TW); CHI-HSUEH LI, Tainan City (TW); CHIEN-CHUN WANG, Tainan City (TW); WEI-TING CHEN, Taoyuan City (TW); WEI-TING CHEN, Taipei City (TW)

(21) Appl. No.: 18/914,599

(22) Filed: Oct. 14, 2024

Related U.S. Application Data
(60) Provisional application No. 63/544,573, filed on Oct. 17, 2023.

(51) Int. Cl. H01L 23/00; H01L 21/48; H01L 23/13; H01L 23/31; H01L 23/498

(52) U.S. Cl. CPC H01L 24/05; H01L 23/13; H01L 23/49822; H01L 23/49833; H01L 24/06; H01L 21/4857; H01L 23/3121; H01L 24/32; H01L 2224/05557; H01L 2224/05559; H01L 2224/06131; H01L 2224/32225; H01L 2924/1815

(57) ABSTRACT

A side-wettable package with edge-recessed bond pads has a composite substrate, and the composite substrate is covered with a molding layer. An upper redistribution layer is formed on the molding layer, and the upper redistribution layer is covered with a solder mask and part of the upper redistribution is exposed to form at least one surface bond pad. Surfaces of each surface bond pad are formed with an anti-oxidation conductive layer, wherein at least one side surface of each surface bond pad is recessed relative to side surfaces of the molding layer. The present invention does not form the side-wettable structure by cutting the upper redistribution layer to prolong service life of cutting Wheels and structural stability of the package. The anti-oxidation conductive layer increases a contacting area between solder and each surface bond pad, thereby facilitating AOI instruments to determine soldering condition of the package and another component.

### CROSS REFERENCE TO RELATED APPLICATIONS

The present application claims benefit of U.S. provisional application No. 63/544,573, filed on Oct. 17, 2023, under 35 U.S.C. 119 (e), the content of which is hereby incorporated by reference in its entirety.

### BACKGROUND OF THE INVENTION

### 1. Field of the Invention

The present invention relates to side-wettable semiconductor packing technology, especially a side-wettable package with edge-recessed bond pads.

### 2. Description of the Related Art

Conventional packages are mainly installed using through-hole technology (THT) or surface mount technology (SMT). The packages using through-hole technology are usually with leads, and the packages using through surface mount technology are without leads. The packages without leads include Quad Flat No-Lead (QFN) package, Dual Flat No-Lead (DFN), etc. The packages without leads are connected and fixed to a circuit board through bond pads formed on their bottom surfaces, and sides of the packages without leads often form side-wettable structures. The side-wettable structures allow solder to adhere thereto, facilitating an Automated Optical Inspection (AOI) to determine whether the packages are well-soldered to the circuit board according to the solder creepage on the sides of the packages.

The bond pads on the bottom surfaces of the packages are often formed by a lead frame or metal layer, and the side-wettable structures are formed by processing the lead frame or metal layer, such as forming an indented portion on the lead frame or cutting the metal layer multiple times to form the indented portion. For example, referring to FIG. 7, a package 80 has a bottom bond pad 81.

The bottom bond pad 81 is cut multiple times to form a indented area 82. The indented area 82 is the side-wettable structure for solder creepage. However, there will be small burrs on a surface of the lead frame or metal layer after cutting, which will affect the adhesion of solder. Furthermore, the lead frame or metal layer may loosen during the process of cutting, which will affect the structural stability of the package. Therefore, the conventional package with the side-wettable structure must be improved.

### SUMMARY OF THE INVENTION

To overcome the aforementioned issue, the present invention provides a side-wettable package with edge-recessed bond pads. The present invention forms a side-wettable structure without affecting structural stability of the package.

In order to achieve the aforementioned objectives, the package of the present invention comprises:

a composite substrate having a conductive layer on an exterior of the composite substrate and an accommodating space in an interior of the composite substrate;

a die mounted in the accommodating space;

a molding layer covering the composite substrate and filling the accommodating space to wrap the die;

an upper redistribution layer mounted on the molding layer and electrically connected to the die and the conductive layer of the composite substrate; and

a solder mask covering the upper redistribution layer and exposing part of the upper redistribution layer to form at least one surface bond pad;

wherein at least one side surface of the at least one surface bond pad is recessed relative to side surfaces of the molding layer, and an anti-oxidation conductive layer is formed on a top surface of each surface bond pad and the at least one side surface of each surface bond pad.

The side-wettable package with edge-recessed bond pads of the present invention defines exposed areas of the upper redistribution layer through the solder mask to form the at least one surface bod pad. The side surfaces of each surface bond pad are recessed relative to the side surfaces of the molding layer, and the anti-oxidation conductive layer is formed on the surfaces of each surface bond pad for solder creepage. The present invention does not form the side-wettable structure by cutting the upper redistribution layer. Since the upper redistribution layer is formed by metal, the present invention is able to reduce wear of cutting wheels and prolong service life of the cutting wheels. Moreover, since the upper redistribution layer is not in contact with the cutting wheels, the impact of stress generated by cutting on the upper redistribution layer can be reduced, or reducing the stress generated by cutting remaining on the upper redistribution. Therefore, the upper redistribution layer will not fall off easily, thereby increasing the structural stability of the package.

The upper redistribution layer of the present invention has not been cut, so that there will be no small burrs on the surface of the upper redistribution layer. When the package of the present invention is soldered to another component (such as a circuit board), the present invention can therefore improve adhesion ability of the solder compared to the prior art. In addition, the at least one side surface of each surface bond pad of the present invention is recessed relative to the side surface of the molding layer. In comparison, the side surface of the bottom bond pad of the prior art is not recessed relative to the edge of the package of the prior art. The present invention has more space for arranging solder, thereby improving the quality of soldering. Moreover, the anti-oxidation conductive layer can increase a contacting area between the solder and each surface bond pad, thereby facilitating AOI instruments to determine soldering condition of the package and another component to stabilize automated production process.

### BRIEF DESCRIPTION OF THE DRAWINGS

FIG. 1 is a cross-sectional side view of a composite substrate of the package of the present invention;

FIGS. 2A to 2P are schematic views of packaging processes of a first embodiment of the package of the present invention, wherein FIG. 2N and FIG. 2P are top side views;

FIGS. 3A to 3N are schematic views of packaging processes of a second embodiment of the package of the present invention;

FIG. 4 is a top side view of a third embodiment of the package of the present invention;

FIG. 5 is a top side view of a fourth embodiment of the package of the present invention;

FIG. 6 is a top side view of a fifth embodiment of the package of the present invention;

FIG. 7 is a cross-sectional side view in partial section of a conventional package.

### DETAILED DESCRIPTION OF THE INVENTION

In order to understand the technical characteristics and practical effects of the prevent invention in detail, and accomplish them according to the content of the present invention, the detailed description is as follows with the embodiments shown in the figures.

The present invention is a side-wettable package with edge-recessed bond pads, wherein the package can be a Panel-Level-Package (PLP) component. The Panel-Level-Package process refers to a process that uses a substrate as a carrier to package one (or more) die that has gone through a production of integrated circuits. Packaging processes and structure of the side-wettable package with edge-recessed bond pads of the present invention are described with figures below.

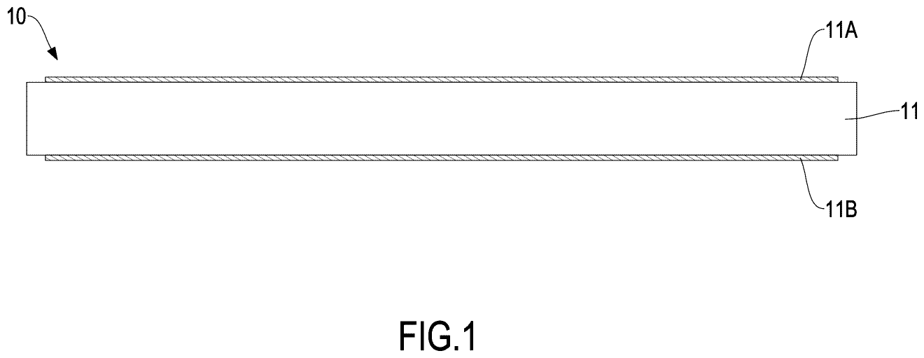

Referring to FIG. 1, FIG. 1 is a cross-sectional view of a composite substrate 10. The composite substrate 10 includes a base layer 11, an upper metal sheet 11A formed on a top surface of the base layer 11, and a lower metal sheet 11B formed on a bottom surface of the base layer 11. For example, the composite substrate 10 can be a copper clad laminate (CCL), that is, the upper metal sheet 11A and the lower metal sheet 11B are respectively a copper foil, and a material of the base layer 11 can be resin.

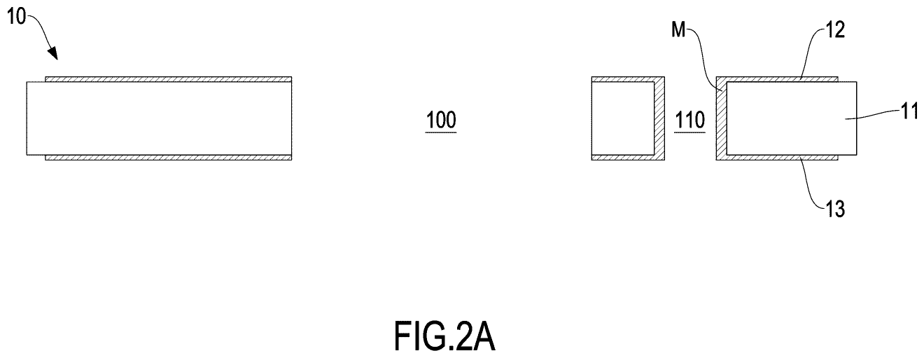

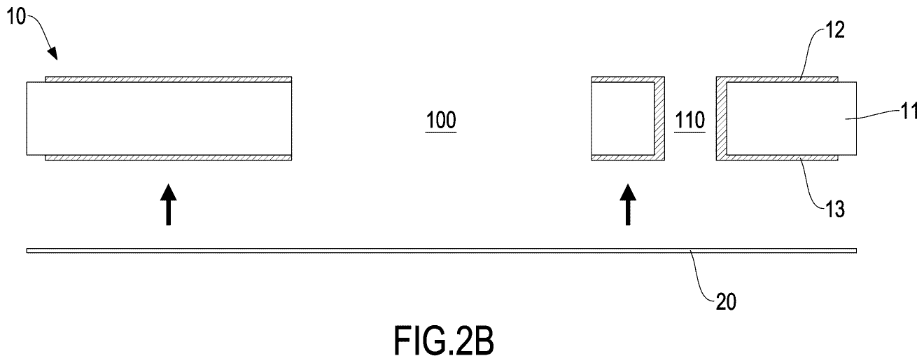

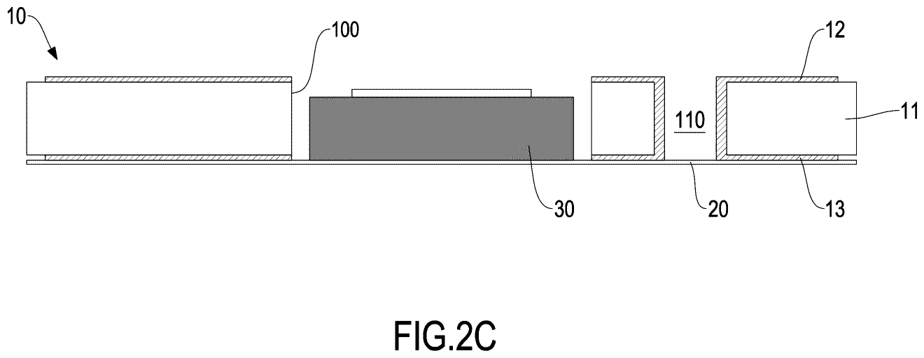

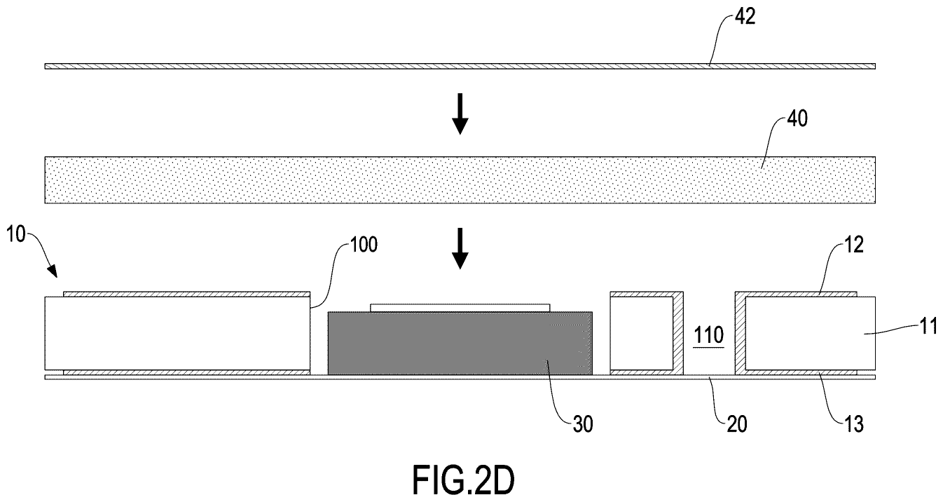

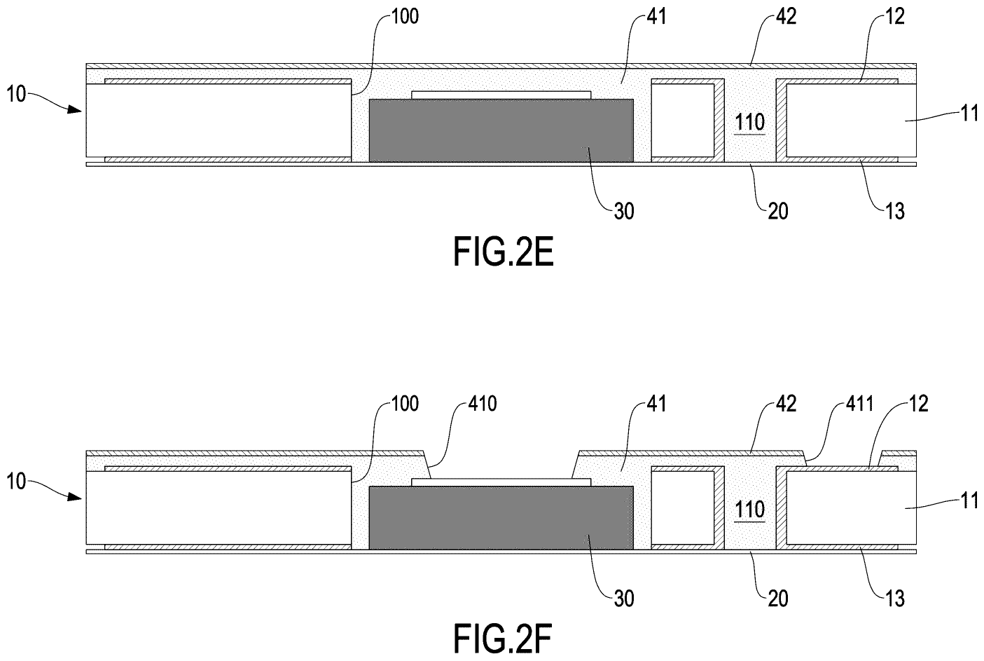

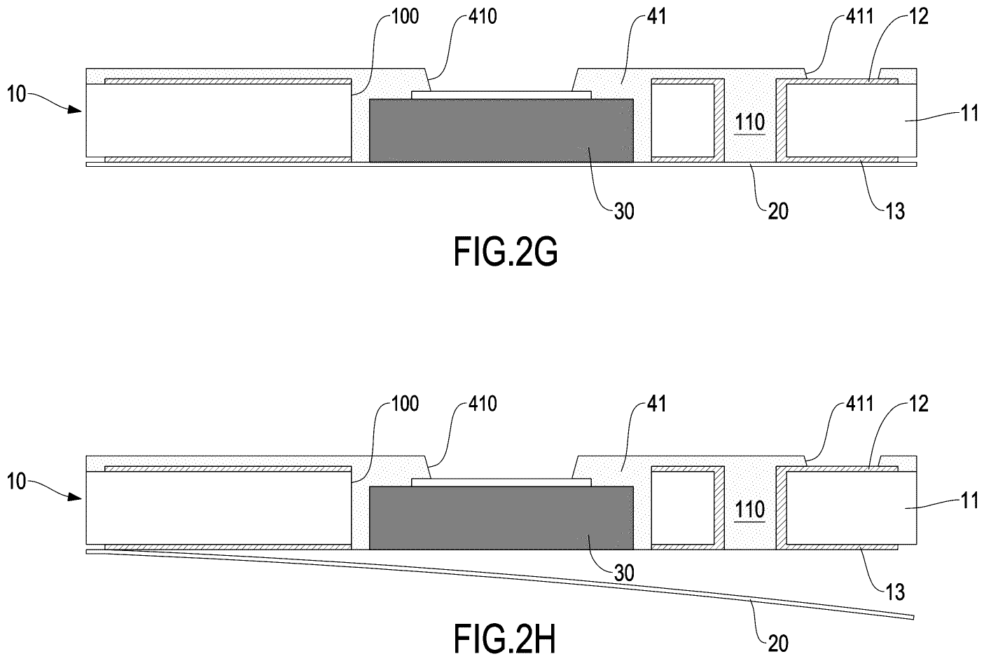

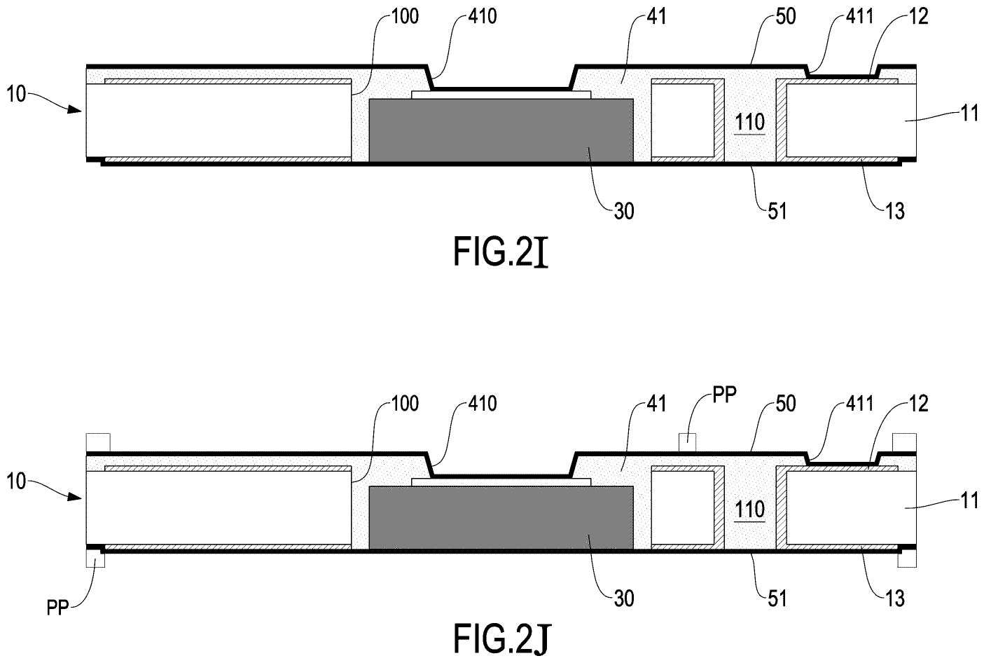

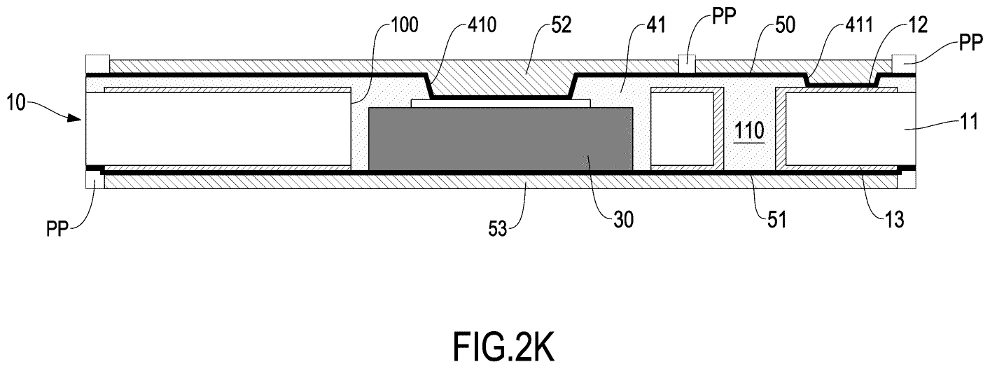

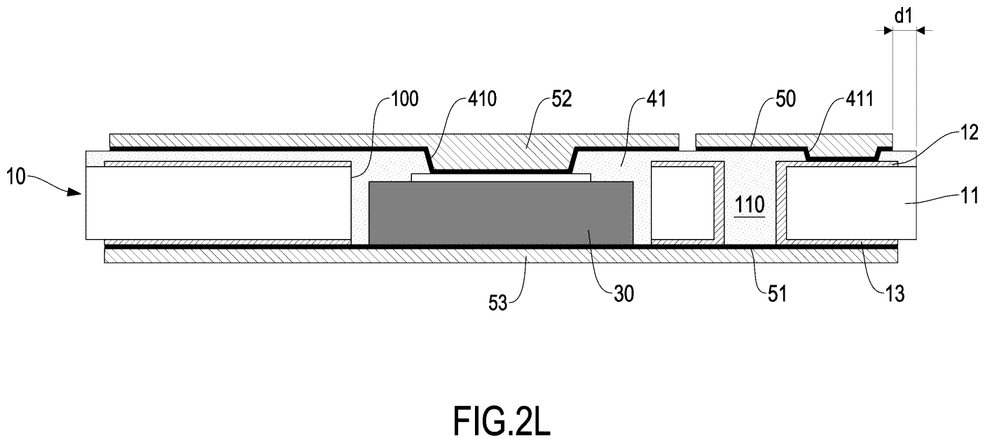

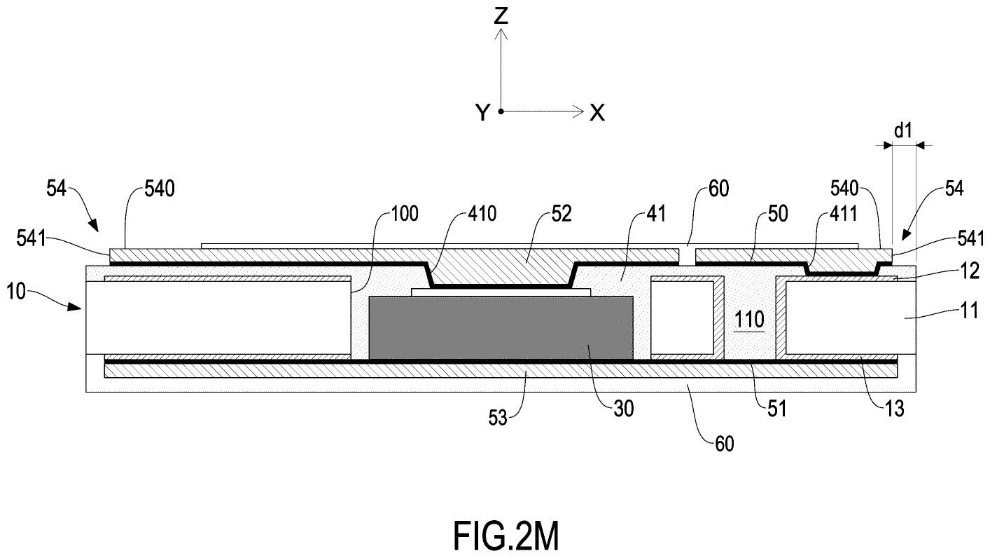

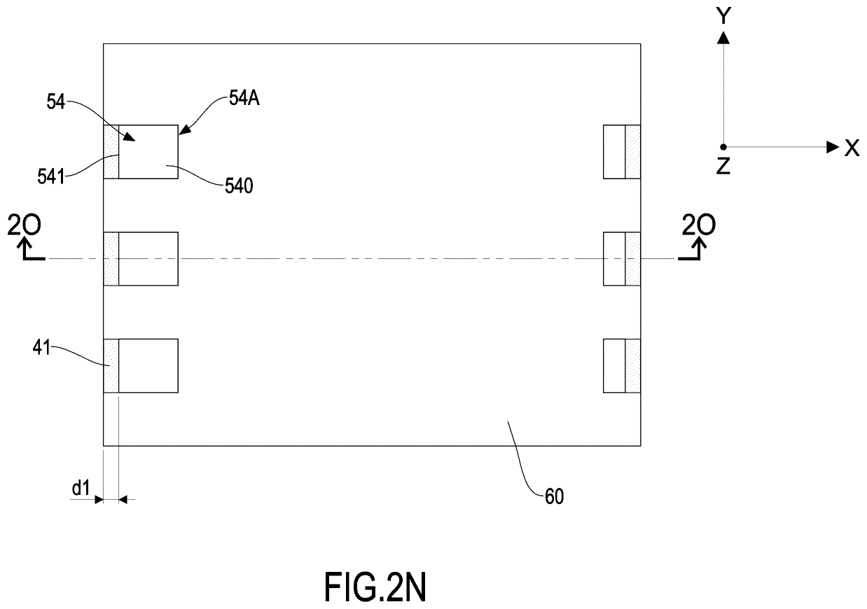

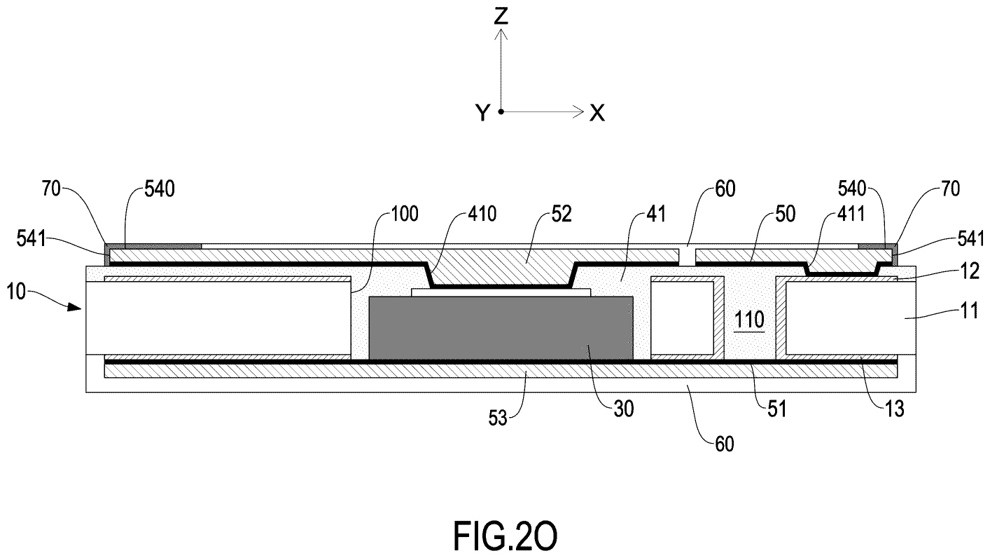

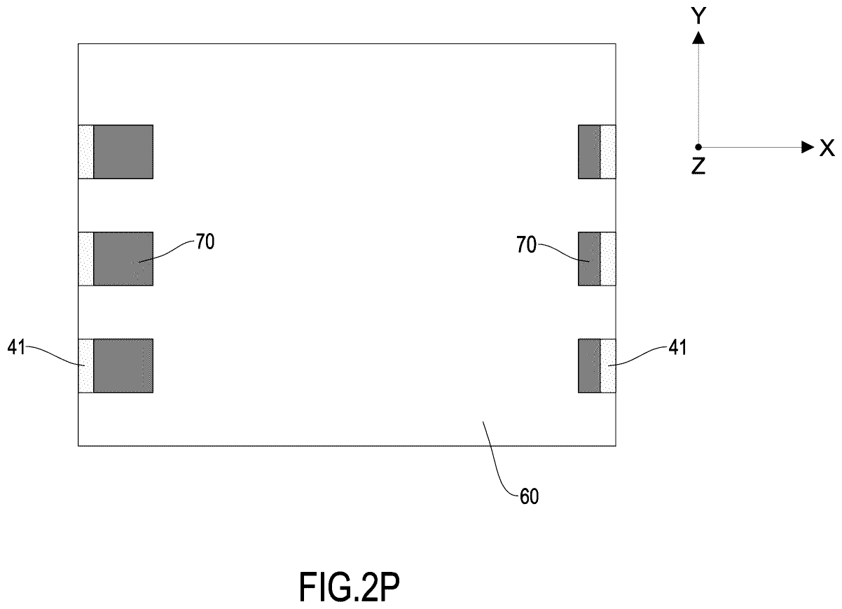

FIGS. 2A to 2P are schematic views of the packaging processes of a first embodiment of the package of the present invention. Referring to FIG. 2A, an accommodating space 100 and at least one plating through hole 110 (PTH) are formed on the composite substrate 10. In particular, a semi-finished package in FIG. 2A is formed by multiple packing processes. First, a drilling process is performed on the composite substrate 10 to form at least one through hole, and then a metal deposition process is performed on the composite substrate 10. A deposited metal M is deposited on an inner wall of the at least one through hole, so that the at least one through hole becomes the at least one plating through hole 110, wherein the deposited metal M can be, for example, copper.

During the metal deposition process, the deposited metal M is deposited outside the composite substrate 10 to form a conductive layer. Specifically, the composite substrate 10 includes an upper conductive layer 12 and a lower conductive layer 13. The upper conductive layer 12 is located on a front surface of the composite substrate, and the upper conductive layer 12 is formed by the upper metal sheet 11A of the composite substrate 10 and the deposited metal M. The lower conductive layer 13 is located on a back surface of the composite substrate, and the lower conductive layer 13 is formed by the lower metal sheet 11B of the composite substrate 10 and the deposited metal M, wherein the upper conductive layer 12 is electrically connected to the lower conductive layer 13 through the at least one plating through hole 110.

Moreover, a drilling process is performed on the composite substrate 10 formed with the at least one plating through hole 110 to form the accommodating space 100 penetrating the composite substrate 10. Referring to FIG. 2B, an adhesive film is attached on the lower conductive layer 13 to seal a bottom of the accommodating space 100. Referring to FIG. 2C, a die 30 is mounted on the adhesive film 20 and within the accommodating space 100. In particular, a bottom surface of the die 30 is fixed on the adhesive film 20, and a top surface and side surfaces of the die 30 are exposed from the accommodating space 100.

Referring to FIG. 2D, an insulating material 40 is placed on the composite substrate 10, and a lamination process is performed on the insulating material 40 to form a molding layer 41 as shown in FIG. 2E. The molding layer 41 covers the composite substrate 10 and fills the accommodating space 100 to wrap the die 30. In particular, the insulating material 40 will melt by heating into a semi-curing (flowable) state during the lamination process to flow and cover the surface of the composite substrate 10. The melted insulating material 40 also fills the accommodating space 100 of the composite substrate 10 and the at least one plating through hole 110. The melted insulating material 40 will solidify to form the molding layer 41 after cooling. The die 30 is wrapped by the molding layer 41 and fixed in the accommodating space 100 of the composite substrate 10. Furthermore, a metal foil 42 can be mounted on the molding layer 41. The metal foil 42 can be formed by plating, sputtering, etc., and the present invention is not limited to the foregoing examples. The metal foil 42 can be a hard mask for subsequent processes to block the laser energy produced by the drilling process.

The next process is to form an upper redistribution layer (RDL) on the molding layer 41. The upper redistribution layer is electrically connected with the die 30 and the conductive layer of the composite substrate 10. In the first embodiment of the present invention, fabrication steps of the upper redistribution layer include the following steps shown in FIGS. 2F to 2L.

Referring to FIG. 2F, at least one first hole 410 and at least one second hole 411 are formed in the molding layer 41. For example, the at least one first hole 410 and the at least one second hole 411 are formed by a laser drilling process. The at least one first hole 410 exposes the top surface of the die 30, and the at least one second hole 411 exposes the conductive layer of the composite substrate 10. Referring to FIG. 2G, a plasma etching process can be performed on the at least one first hole 410 and the at least one second hole 411 to remove residues produced during the drilling process, and an etching process can be performed on the metal foil 42 to remove the metal foil 42. Referring to FIG. 2H, the adhesive film 20 attached on the lower conductive layer 13 is removed to expose the lower conductive layer 13 and the bottom of the accommodating space 100 (the bottom surface of the die 30).

Referring to FIG. 2I, an upper seed layer 50 is formed on the molding layer 41, the at least one first hole 410 and the at least one second hole 411. The upper seed layer 50 can be formed by plating, sputtering, etc., and the present invention is not limited to the foregoing examples. While forming the upper seed layer 50, a lower seed layer 51 can also be formed on a bottom surface of the lower conductive layer 13 and a bottom surface of the accommodating space 100 (the bottom surface of the die 30).

An upper metal layer 52 is formed on the upper seed layer 50 by an additive process. That is, the upper seed layer 50 and the upper metal layer 52 are sequentially stacked on the molding layer 41. Regarding how to form the upper metal layer 52 through the additive process, referring to FIG. 2J, a photo pattern PP is arranged on the upper seed layer 50. The photo pattern PP covers edges of a top surface of the upper seed layer 50. As shown in FIG. 2K, the upper metal layer 52 is formed by plating on the upper seed layer 50 and in areas other than the photo pattern PP. For example, material of the upper metal layer 52 can be copper. Similarly, a lower metal layer 53 can also be formed on the lower seed layer 51 through the additive process. The formation process of the lower metal later 53 is same as the formation process of the upper metal layer 52 mentioned above and will not be described again.

Referring to FIG. 2L, the packaging process is to remove the photo pattern PP on the molding layer 41 and the upper seed layer 50 under the photo pattern PP, and remove the photo pattern PP on the bottom surface of the composite substrate 10 and the lower seed layer 51 under the photo pattern PP. The upper seed layer 50 and the upper metal layer 52 together form the upper redistribution layer, and the lower seed layer 51 and the lower metal layer 53 together form a lower redistribution layer. Side surfaces of the upper redistribution layer and side surfaces of the lower redistribution layer are respectively recessed to the side surface of the composite substrate 10. Furthermore, the upper conductive layer 12 of the composite substrate 10 is electrically connected with the top surface of the die 30 through the upper redistribution layer, and the lower conductive layer 13 of the composite substrate 10 is electrically connected with the bottom surface of the die 30 through the lower redistribution layer.

Referring to FIG. 2M, a solder mask 60 is formed on the upper redistribution layer. The solder mask 60 does not cover edges of the upper metal layer 52 to define at least one surface bond pad 54. In particular, the solder mask 60 covers the upper redistribution layer. The edges of the upper redistribution layer are exposed to the solder mask 60 to form at least one surface bond pad 54. That is, the at least one surface bond pad 65 is formed by the upper metal layer 52 and the upper seed layer 50. A top surface 540 of the at least one surface bond pad 54 is not covered by the solder mask 60 and is exposed on the top of the package of the present invention. The top surface 540 of the at least one surface bond pad 54 is the top surface of the upper metal layer 52.

A side peripheral wall of the at least one surface bond pad 54 includes at least one side surface. The at least one side surface is formed by the side surface of the upper metal layer 52 and the side surface of the upper seed layer 50.

Referring to FIG. 2N, for example, the at least one surface bond pad 54 may be a first surface bond pad 54A. The side surface of the first surface bond pad 54 is recessed relative to one side surface of the package (the side surface of the molding layer 41). The first surface bond pad 54A is the surface bond pad 54 comprising a first side surface 541. As shown in FIG. 2N, the first side surface 541 is exposed to the side surface of the package, and the first side surface 541 is recessed relative to the side surface of the molding layer 41.

In the present embodiment, the top surface 540 of each first surface bond pad 54 and the at least one side surface (the first side surface 541) of each first surface bond pad 54 are respectively flat surfaces. An angle between the top surface 540 and the at least one side surface of each surface bond pad 54 may be less than, equal to, or greater than 90 degrees, depending on different factors in the etching process, such as the composition of the etchant, the length of the etching time, etc., and the present invention is not limited to the foregoing examples. In addition, there is a recessed distance d1 between the first side surface 541 and the side surface of the molding layer 41, and the upper metal layer has a thickness. The thickness is equal to the recessed distance d1. For example, the recessed distance d1 and the thickness can be between 50 and 200 micro meters, preferably between 100 and 150 micro meters, and the present invention is not limited to the foregoing example.

Referring to FIG. 2M, the solder mask 60 also covers the lower metal layer 53 of the lower redistribution layer. Since the side surfaces of the lower redistribution layer are recessed relative to the side surfaces of the composite substrate 10, the solder mask 60 will be filled between the side surface of the lower redistribution layer and the side surface of the composite substrate 10. The solder mask 60 has functions of waterproofness and oxidation prevention. The solder mask 60 is distributed between circuits of the upper redistribution layer and between circuits of the lower redistribution layer to prevent adjacent circuits to be short.

Referring to FIG. 2O and FIG. 2P, an anti-oxidation conductive layer 70 is formed on the top surface 540 and the at least one side surface of each surface bond pad 54. The anti-oxidation conductive layer 70 is a side-wettable flank, and material of the anti-oxidation conductive layer 70 can be metal such as tin, gold, etc., and the present invention is not limited to the foregoing examples. When the package of the present invention is soldered to a circuit board (not shown in Figs), the anti-oxidation conductive layer 70 can be adopted for solder adsorption, so that each surface bond pad 54 can be mounted on the circuit board through solder and be electrically connected to the circuit board. The structure of the anti-oxidation layer 70 increases a contacting area between the solder and each surface bond pad 54. Therefore, an Automated Optical Inspection instrument can photograph contacting situations between the package of the present invention and the circuit board to determine whether the package is firmly soldered to the circuit board.

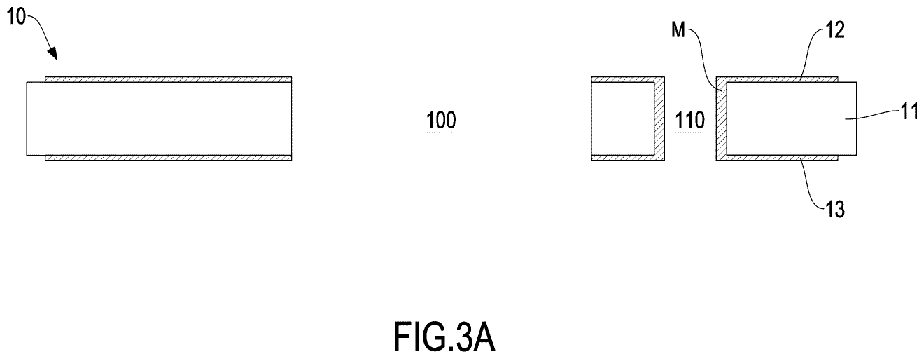

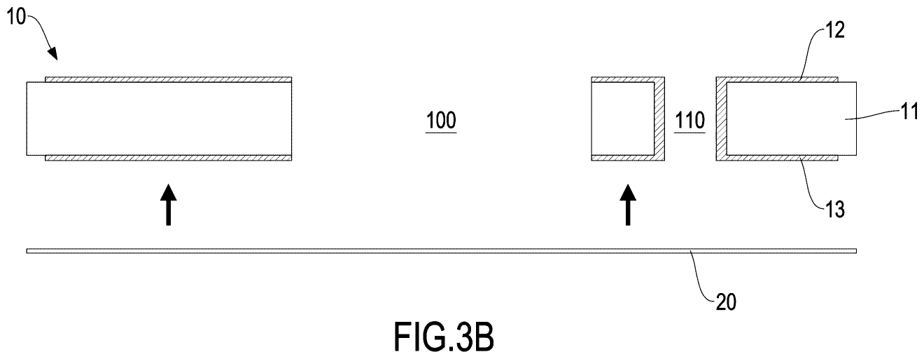

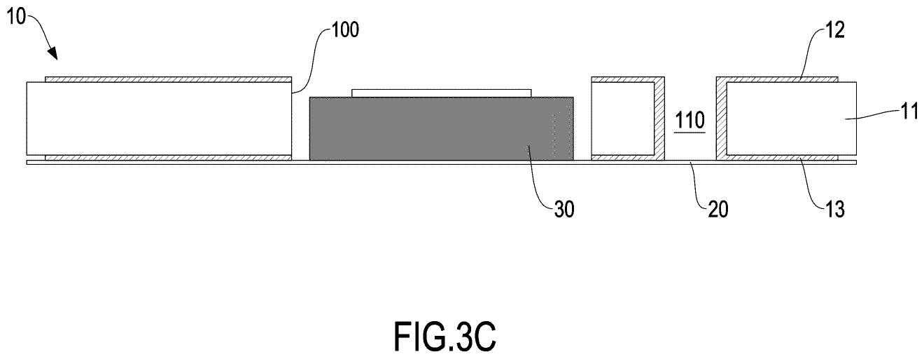

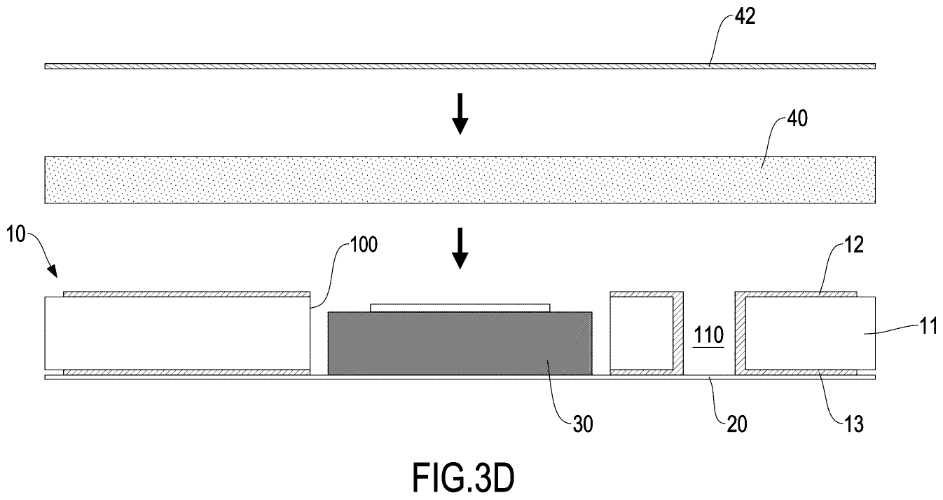

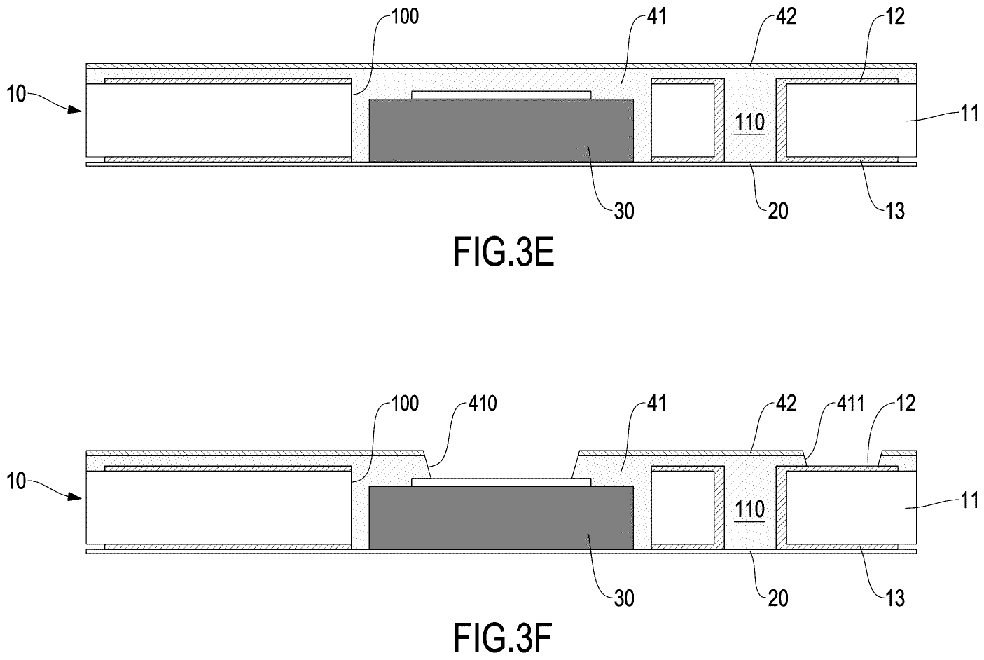

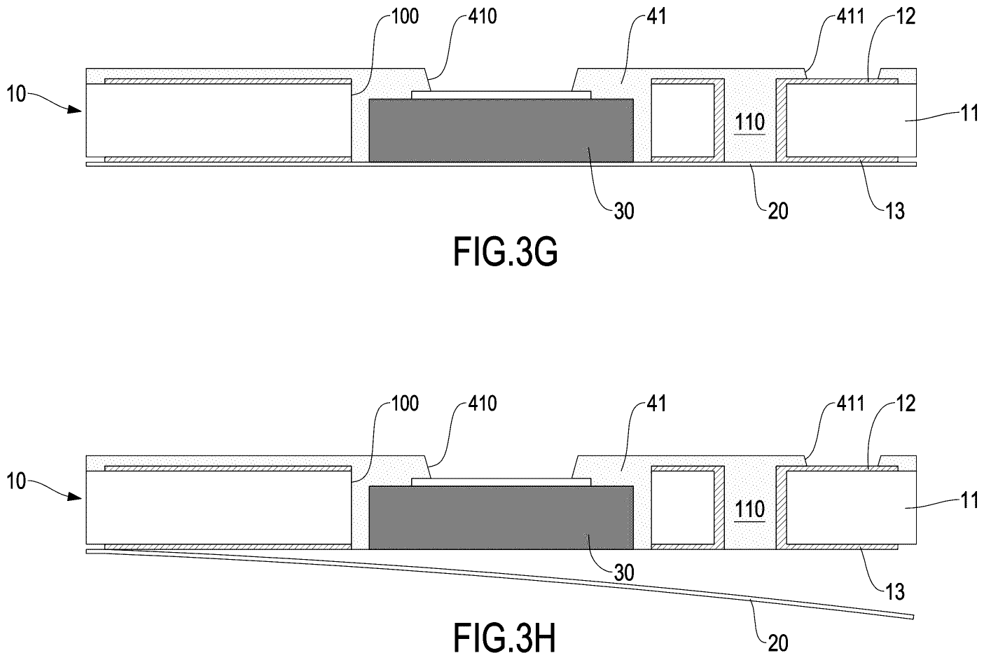

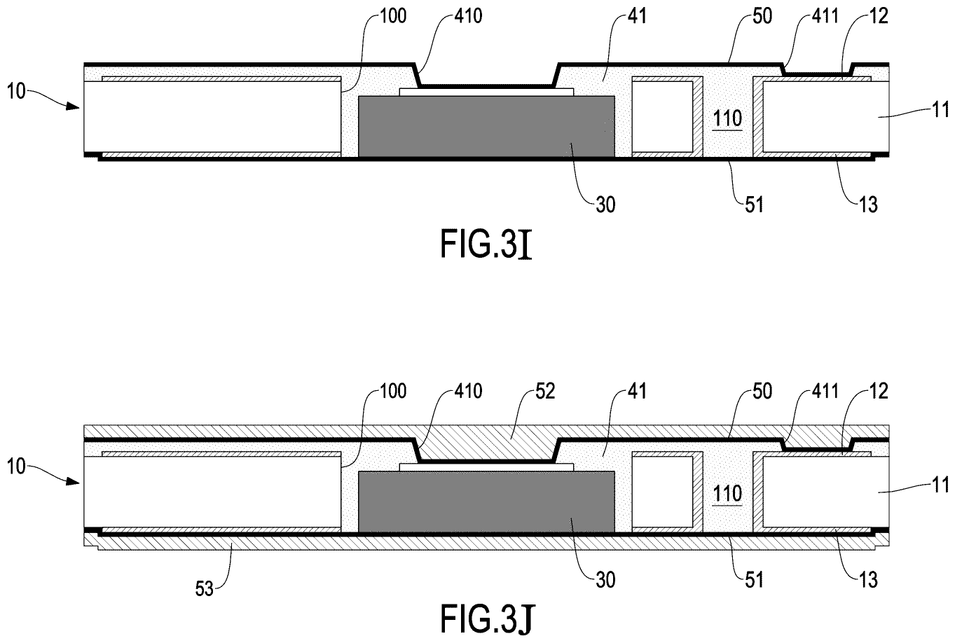

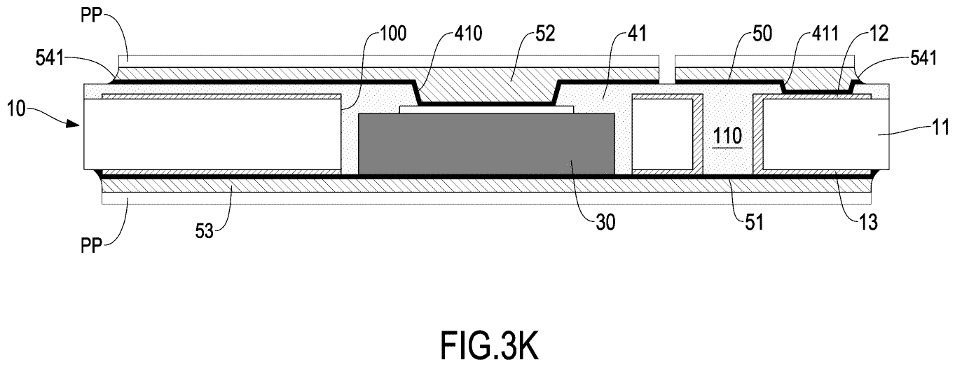

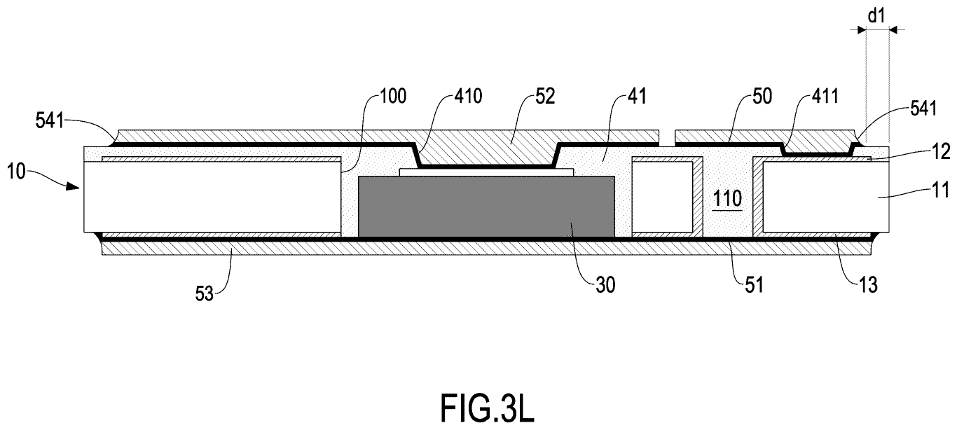

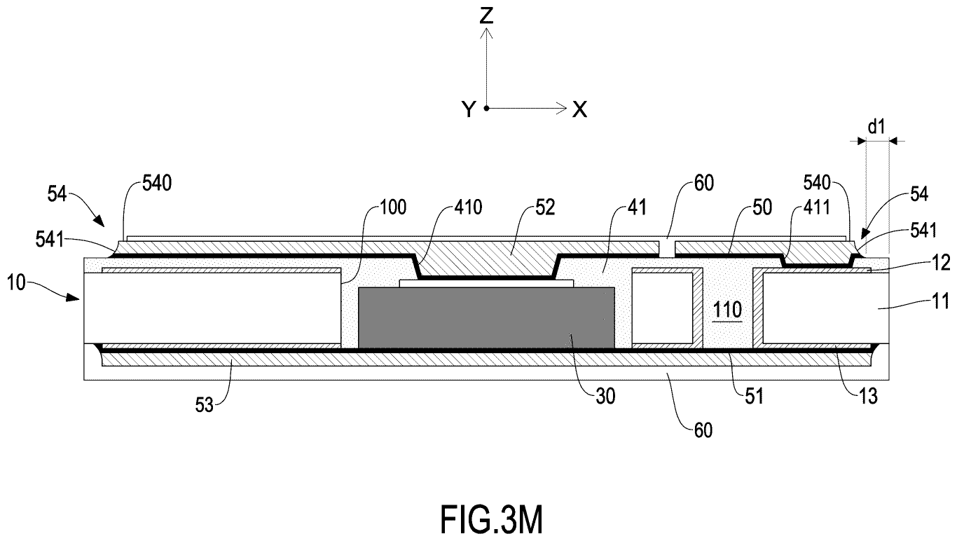

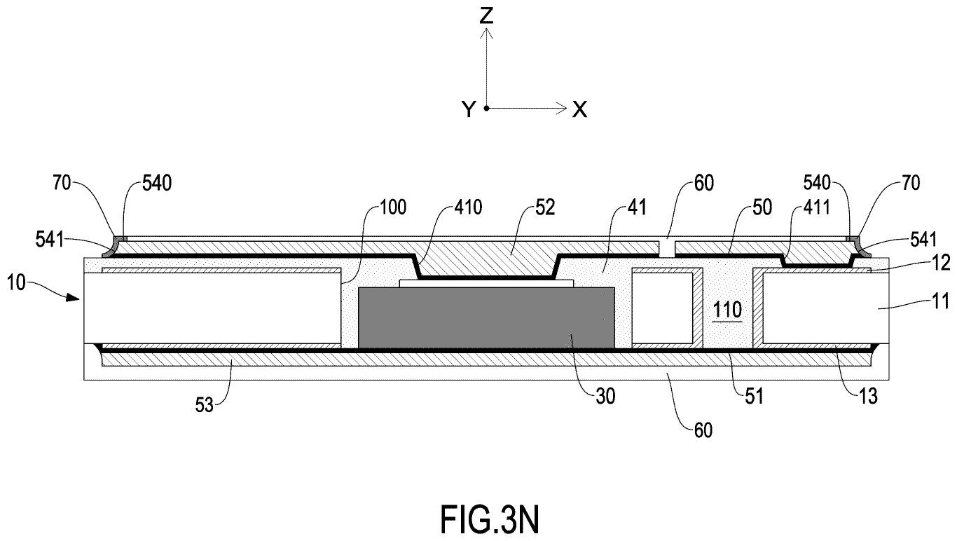

After completing the processes shown in FIGS. 2A to 2P, the first embodiment of the side-wettable package with edge-recessed bond pads of the present invention (as shown in FIGS. 2O and 2P) is formed. The package of the present invention also has a second embodiment. The second embodiment of the package is also formed by packaging the composite substrate 10 as shown in FIG. 1. Referring to FIGS. 3A to 3N, FIGS. 3A to 3N are schematic views of the packaging processes of the second embodiment of the side-wettable package with edge-recessed bond pads of the present invention, wherein the packaging processes in FIGS. 3A to 31 are same as the packaging processes in FIGS. 2A to 2I and will not be described again. A difference between the second embodiment and the first embodiment of the package of the present invention is the packaging processes in FIGS. 3J and 3K. The packaging processes in FIGS. 3J to 3K are to form the upper metal layer 52 through a subtractive process.

Referring to FIG. 3J, after the upper seed layer 50 is formed on the molding layer 41, the at least one first hole 410 and the at least one second hole 411, the upper metal layer 52 can be formed on the upper seed layer 50 by tenting. In the same way, the lower metal layer 53 is formed on the lower seed layer 51.

Referring to FIG. 3K, the photo pattern PP is respectively mounted on the upper metal layer 52 and the lower metal layer 53, and the photo pattern PP does not cover edges of the top surface of the upper metal layer 52. The upper seed layer 50, the upper metal layer 52, the lower seed layer 51, and the lower metal layer 53 that are not covered by the photo pattern PP are etched, so that the side surface of the upper seed layer 50 and the upper metal layer 52 are recessed relative to the side surface of the composite substrate 10, and the side surface of the lower seed layer 51 and the lower seed layer 53 are recessed relative to the side surface of the composite substrate 10, wherein the at least one side surface of the surface bond pad 54 is formed by the side surface of the upper seed layer 50 and the side of the upper metal layer 52. Since the at least one side surface is formed by etching, the at least one side surface (the first side surface 541) is an arc surface. Similarly, the side surface of the lower seed layer 51 and the side surface of the lower metal layer 53 are each respectively an arc surface.

Referring to FIG. 3L, the photo pattern PP on the upper metal layer 52 and the lower metal layer 53 is removed, so that the top surface of the upper metal layer 52 and the bottom surface of the lower metal layer 53 are exposed. Referring to FIG. 3M, the solder mask 60 is covered on part of the upper metal layer 52 (the upper redistribution), and part of the upper redistribution is exposed to form the at least one surface bond pad 54. The top surface 540 of each surface bond pad 54 and the at least one side surface of each surface bond pad 54 are respectively a flat surface and an arc surface, wherein the at least one side surface of the at least one surface bond pad 54 is recessed relative to at least one side surface of the package of the present invention as the first embodiment of the present invention. The lower metal layer 53 of the lower redistribution layer is also covered with the solder mask 60, and the solder mask 60 is filled between the side surface of the lower redistribution layer and the side surface of the composite substrate 10. Referring to FIG. 3N, forming the anti-oxidation conductive layer 70 on the top surface 540 and the at least one side surface of each surface bond pad to complete the second embodiment of the side-wettable package with edge-recessed bond pads of the present invention. Since the side surfaces of the package in the first embodiment and the second embodiment are respectively a flat surface and an arc surface, the structure of the anti-oxidation conductive layer 70 of the package in the first embodiment is different from the structure of the anti-oxidation conductive layer 70 of the package in the second embodiment.

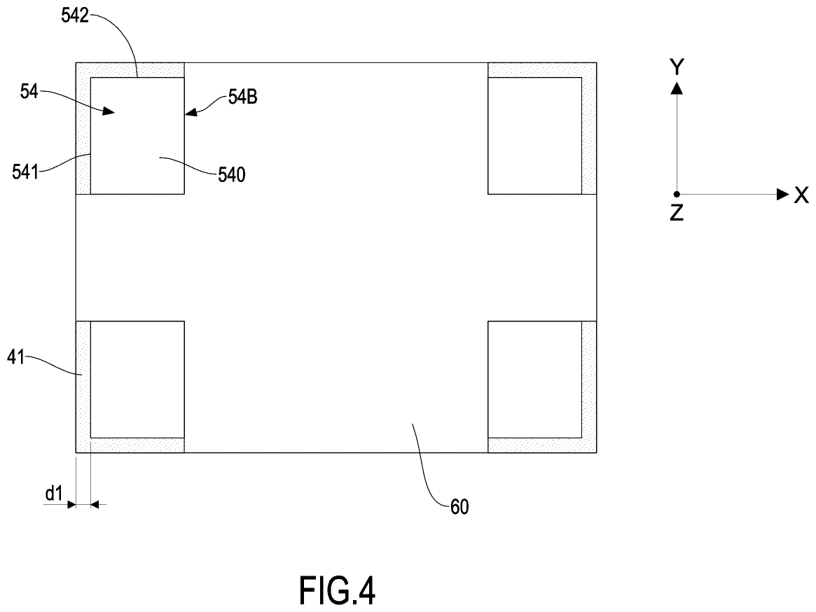

Since the at least one surface bond pad 54 in the present invention is defined and formed by the solder mask 60, the at least one surface bond pad 54 can be formed with different numbers of exposing side surfaces according to the coverage of the upper redistribution layer by the solder mask 60. In addition to the first surface bond pad 54A (with one exposing side surface) above mentioned, the following are three configurations of the at least one surface bond pad 54 that the package of the present invention may also include. Referring to FIGS. 4 to 6, the side surface of the three configurations of the at least one surface bond pad 54 are recessed relative to at least one side surface of the package (the side surface of the molding layer 41).

1. A second surface bond pad 54B: referring to FIG. 4, the second surface bond pad 54B is the surface bond pad 54 with the side peripheral wall including a first side surface 541 and a second side surface 542. The first side surface 541 is connected to the second side surface 542. In an X-axis direction of the package as shown in FIG. 4, the first side surface 541 is recessed relative to the side surface of the molding layer 41. In a Y-axis direction of the package, the second side surface 542 is recessed relative to the side surface of the molding layer 41. As for the first side surface 541 recessed along the positive direction of the X-axis or the negative direction of the X-axis, and the second side 542 recessed along the positive direction of the Y-axis or along the negative direction of the Y-axis, the present invention is not limited to.

The X-axis and Y-axis are adopted to describe that the first side surface 541 and the second side surface 542 are respectively recessed relative to the side surfaces of the molding layer 41 along two different directions. The present invention does not limit that the first side surface 541 can only be recessed along the X-axis direction of the package, and the second side surface 542 can only be recessed along the Y-axis direction of the package. That is, the first side surface 541 can also be recessed relative to the side surface of the molding layer 41 along the Y-axis direction of the package, and the second side surface 542 can also be recessed relative to the side surface of the molding layer 41 along the X-axis direction of the package.

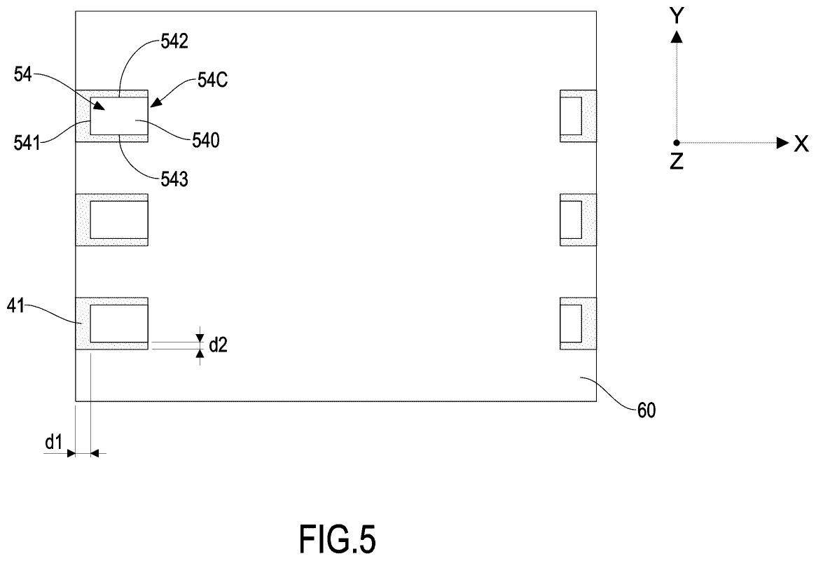

2. A third surface bond pad 54C: referring to FIG. 5, the third surface bond pad 54C is the surface bond pad 54 with the side peripheral wall including a first side surface 541, a second side surface 542, and a third side surface 543. The first side surface 541 of the third surface bond pad 54C is recessed relative to the side surface of the molding layer 41 along the X-axis direction, and the second side surface 542 and the third side surface 543 are located on opposite sides of the third surface pad 54C. In the Y-axis direction of the package, the second side surface 542 and the third side surface 543 are recessed relative to the edges of the solder mask 60. For example, the first side surface 541 of the third surface bond pad 54C is recessed relative to the side surface of the molding layer 41 along the positive direction of the X-axis, and the second side surface 542 and the third side surface 543 are respectively recessed relative to the edges of the solder mask 60 along the negative direction of the Y-axis and the positive direction of the Y-axis. That is, there is an interval distance d2 between the second side surface 542 and the edge of the solder mask 60, and between the third side surface 543 and the edge of the solder mask 60. For example, the interval distance d2 can be between 50 and 200 micro meters, preferably between 100 and 150 micro meters, and the present invention is not limited to the foregoing example.

Please note that the first side surface 541 of the third surface bond pad 54C is recessed relative to the side surface of the molding layer 41 along one axis, and the second side surface 542 and the third side surface 543 are recessed relative to the edges of the solder mask 60 along another axis different from the axis aforementioned. The present invention does not limit that the first side surface 541 can only be recessed along the X-axis direction of the package, and the second side surface 542 and the third side surface 543 can only be recessed along the Y-axis direction of the package. The first side surface 541 is recessed relative to the side surface of the molding layer 41, and the second side surface 542 and the third side surface 543 are recessed relative to the edges of the solder mask 60. That is to say, the first side surface 541 can also be recessed relative to the side surface of the molding layer 41 along the Y-axis of the package, the second side surface 542 and the third side surface 543 can be recessed relative to the edges of the solder mask 60 along the X-axis of the package, wherein the second side surface 542 and the third side surface 543 are respectively recessed relative to the edges of the solder mask 60 along two opposite directions of the X-axis.

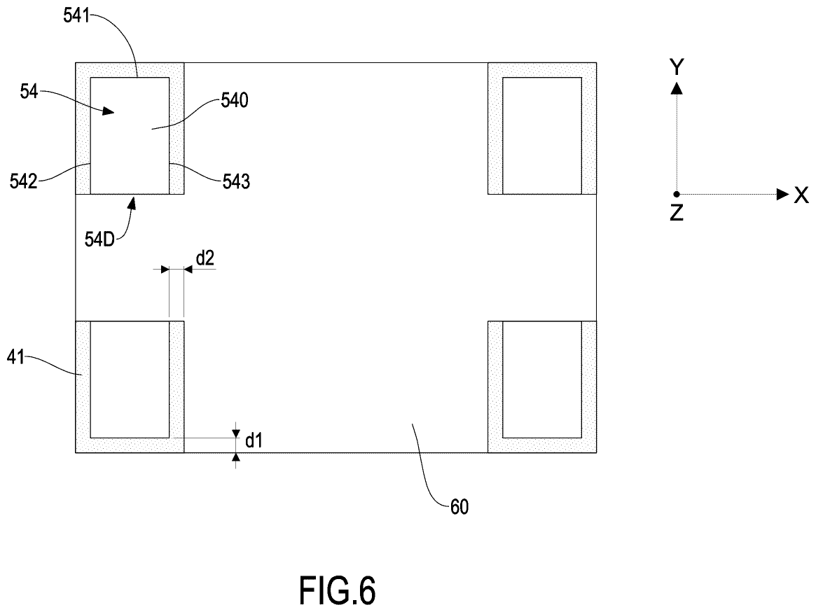

3. A fourth surface bond pad 54D: referring to FIG. 6, the fourth surface bond pad 54C is the surface bond pad 54 with the side peripheral wall including a first side surface 541, a second side surface 542, and a third side surface 543.

The first side surface 541 of the fourth surface bond pad 54D is recessed relative to the side surface of the molding layer 41 along the Y-axis direction, and the second side surface 542 and the third side surface 543 are located on opposite sides of the fourth surface bond pad 54D. In the X-axis direction of the package, one of the second side surface 542 and the third side surface 543 is recessed relative to the edge of the solder mask 60, and the other of the second side surface 542 and the third side surface 543 is recessed relative to the side surface of the molding layer 41. For example, the first side surface 541 of the fourth surface bond pad 54D is recessed relative to the side surface of the molding layer 41 along the negative direction of the Y-axis, the second side surface 542 is recessed relative to the side surface of the molding layer 41 along the positive direction of the X-axis, and the third side surface 543 is recessed relative to the edge of the solder mask 60 along the negative direction of the X-axis. There is the recessed distance d1 between the first surface 541 and the molding layer 41, and between the second surface 542 and the molding layer 41. There is the interval distance d2 between the third side surface 543 and the edge of the solder mask 60.

Please note that the first side surface 541 of the fourth surface bond pad 54D is recessed relative to the side surface of the molding layer 41 along one axis, one of the second side surface 542 and the third side surface 543 is recessed relative to the side surface of the molding layer 41 along another axis different from the axis aforementioned, and the other of the second side surface 542 and the third side surface 543 is recessed relative to the edge of the solder mask 60 along another said axis. That is, the first side surface 541 can also be recessed along the X-axis direction of the package, and the second side surface 542 and the third side surface 543 can also be recessed along the Y-axis direction of the package.

The side-wettable package with edge-recessed bond pads of the present invention defines the exposed areas of the upper redistribution layer through the solder mask 60 to form the at least one surface bod pad 54. The side surfaces of each surface bond pad 54 are recessed relative to at least one side surface of the package (the side surfaces of the molding layer 41), and the anti-oxidation conductive layer 70 is formed on the surfaces (the top surface 540 and the at least one side surface) of each surface bond pad 54 for solder creepage. The present invention does not form the side-wettable structure by cutting the upper redistribution layer. Since the upper redistribution layer is formed by metal (the upper metal layer), the present invention is able to reduce wear of cutting wheels and prolong service life of the cutting wheels. Moreover, since the upper redistribution layer is not in contact with the cutting wheels, the impact of stress generated by cutting on the upper redistribution layer can be reduced, or reducing the stress generated by cutting remaining on the upper redistribution. Therefore, the upper redistribution layer will not fall off easily, thereby increasing structural stability of the package.

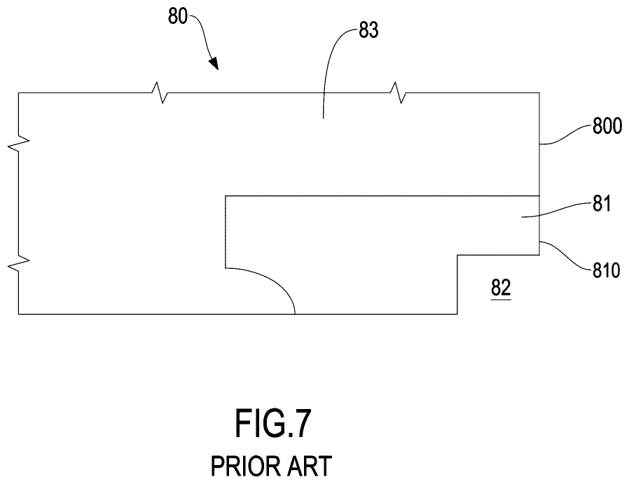

The upper metal layer 52 of the present invention has not been cut, so that there will be no small burrs on the surface of the upper metal layer 52. When the package of the present invention is soldered to another component (such as a circuit board), the present invention can therefore improve adhesion ability of the solder compared to the prior art. In addition, the at least one side surface of each surface bond pad 54 of the present invention is recessed relative to the side surface of the molding layer 41. In comparison, as shown in FIG. 7, the side surface 810 of the bottom bond pad 81 of the prior art is not recessed relative to the edge 800 of the package 80. In other words, as shown in FIG. 2P, the surface bond pad 54 of the present invention is recessed to expose the molding layer 41, and the molding layer 83 of the package 80 in FIG. 7 is covered by the bottom bond pad 81 and is not exposed. Therefore, compared with the prior art, the present invention has more space for arranging the solder, thereby improving the quality of soldering. As mentioned above, the anti-oxidation conductive layer 70 can increase a contacting area between the solder and each surface bond pad 54, thereby improving inspecting ability of the instrument during Automated Optical Inspection of the package to stabilize automated production process.

The above only records the implementations or embodiments of the technical artifices adopted by the present invention to solve the problems, and is not configured to limit the claims of the present invention. That is, all equivalent changes and modifications that are consistent with the meaning of the claims of the present invention or made in accordance with the claims of the present invention are covered by the claims of the present invention.

What is claimed is:

1. A side-wettable package with edge-recessed bond pads, comprising:
a composite substrate having a conductive layer on an exterior of the composite substrate and an accommodating space in an interior of the composite substrate;
a die mounted in the accommodating space;
a molding layer covering the composite substrate and filling the accommodating space to wrap the die;
an upper redistribution layer mounted on the molding layer and electrically connected to the die and the conductive layer of the composite substrate; and
a solder mask covering the upper redistribution layer and exposing part of the upper redistribution layer to form at least one surface bond pad;
wherein at least one side surface of the at least one surface bond pad is recessed relative to side surfaces of the molding layer, and an anti-oxidation conductive layer is formed on a top surface of each surface bond pad and the at least one side surface of each surface bond pad.

2. The package as claimed in claim 1, wherein the at least one surface bond pad comprises a first side surface and a second side surface, and the first side surface and the second side surface are recessed relative to the side surfaces of the molding layer along two different directions.

3. The package as claimed in claim 1, wherein the at least one surface bond pad comprises a first side surface, a second side surface, and a third side surface, the first side surface is recessed relative to the side surface of the molding layer along one axis, and the second side surface and the third side surface are recessed relative to edges of the solder mask along two opposite directions of another axis.

4. The package as claimed in claim 1, wherein the at least one surface bond pad comprises a first side surface, a second side surface, and a third side surface, the first side surface is recessed relative to the side surface of the molding layer along one axis, one of the second side surface and the third side surface is recessed relative to an edge of the solder mask along another axis, and the other of the second side surface and the third side surface is recessed relative to the side surface of the molding layer along another said axis.

5. The package as claimed in claim 1, wherein the top surface of each surface bond pad and the at least one side surface of each surface bond pad are flat surfaces.

6. The package as claimed in claim 1, wherein the top surface of each surface bond pad and the at least one side surface of each surface bond pad are respectively a flat surface and an arc surface.

7. The package as claimed in claim 1, wherein a recessed distance is defined between the at least one side surface of each surface bond pad and the side surface of the molding layer, and the recessed distance is between 50 and 200 micro meters.

8. The package as claimed in claim 7, wherein the upper redistribution layer comprises an upper seed layer and an upper metal layer, the upper seed layer and the upper metal layer are sequentially stacked on the molding layer; and the upper metal has a thickness equal to the recessed distance.

9. The package as claimed in claim 1, wherein the conductive layer of the composite substrate comprises an upper conductive layer and a lower conductive layer, the upper conductive layer and the lower conductive layer are respectively located on a front surface of the composite substrate and a back surface of the composite substrate; the upper conductive layer is electrically connected to the lower conductive layer through at least one plating through hole in the composite substrate.

10. The package as claimed in claim 9, wherein a lower redistribution layer is formed on the lower conductive layer of the composite substrate and the bottom surface of the die, and side surfaces of the lower redistribution layer are recessed relative to side surfaces of the composite substrate.
